(19) United States
(12) Patent Application Publication
(10) Pub. No.: US 2024/0021539 A1
(43) Pub. Date: Jan. 18, 2024

(54) SEMICONDUCTOR DEVICE AND METHOD OF MANUFACTURING THE SAME

(71) Applicant: SAMSUNG ELECTRONICS CO., LTD., Suwon-si (KR)

(72) Inventor: JOO-YOUNG OH, Suwon-si (KR)

(73) Assignee: SAMSUNG ELECTRONICS CO., LTD., Suwon-si (KR)

(21) Appl. No.: 18/117,848

(22) Filed: Mar. 6, 2023

(30) Foreign Application Priority Data
Jul. 12, 2022 (KR) 10-2022-0085704

(51) Int. Cl. H01L 23/00; H01L 21/66

(52) U.S. Cl. CPC H01L 23/562; H01L 22/32

(57) ABSTRACT

A semiconductor device includes a semiconductor substrate including a device region and an edge region; a semiconductor component on the device region; a metal structure on the edge region; an insulating layer surrounding the semiconductor component and the metal structure; and a pad on the semiconductor component, wherein the metal structure is surrounded by the insulating layer and is not exposed at a side surface of the insulating layer, and wherein the metal structure is electrically insulated from the semiconductor component.

### CROSS-REFERENCE TO RELATED APPLICATIONS

This application is based on and claims priority under 35 U.S.C. § 119 to Korean Patent Application No. 10-2022-0085704, filed on Jul. 12, 2022, in the Korean Intellectual Property Office, the disclosures of which are incorporated by reference herein in their entireties.

### BACKGROUND

### 1. Field

The present disclosure relates to a semiconductor device and a method of manufacturing the same, and more particularly, to a semiconductor device including a test pattern on a scribe lane region and a method of manufacturing the same.

### 2. Description of Related Art

Typically, a wafer on which semiconductor devices are formed may include chip regions on which the semiconductor devices are formed, and a scribe lane dividing the chip regions. A plurality of semiconductor components (e.g., a transistor, a resistance, a capacitor, etc.) may be formed on the chip region but may not be formed on the scribe lane, and the wafer may be sawn along the scribe lane to complete semiconductor chips divided from each other. Test patterns for monitoring electrical characteristics and failure or not of the semiconductor components provided on the chip region to check whether processes are normally performed or not and/or an alignment key for an exposure process may be disposed on the scribe lane.

### SUMMARY

Provided are a semiconductor device with improved structural stability and a method of manufacturing the same.

Provided are a method of manufacturing a semiconductor device which is capable of reducing or minimizing occurrence of failure, and a semiconductor device manufactured by the same.

In accordance with an aspect of the disclosure, a semiconductor device includes a semiconductor substrate including a device region and an edge region; a semiconductor component on the device region; a metal structure on the edge region; an insulating layer surrounding the semiconductor component and the metal structure; and a pad on the semiconductor component, wherein the metal structure is surrounded by the insulating layer and is not exposed at a side surface of the insulating layer, and wherein the metal structure is electrically insulated from the semiconductor component.

In accordance with an aspect of the disclosure, a semiconductor device includes a semiconductor substrate including a device region and an edge region which surrounds the device region; a semiconductor component on a top surface of the device region; a metal structure on a top surface of the edge region; an interconnection layer on the semiconductor component and the metal structure; and a pad on the interconnection layer on the device region, wherein the pad is electrically connected to the interconnection layer, and wherein the metal structure is spaced apart from a side surface of the semiconductor substrate in a direction toward an inside of the semiconductor substrate.

In accordance with an aspect of the disclosure, a method of manufacturing a semiconductor device includes providing a semiconductor substrate having a first device region, a second device region, and a scribe lane between the first device region and the second device region; forming a first semiconductor component on the first device region and a second semiconductor component on the second device region; forming metal structures on the scribe lane of the semiconductor substrate, wherein the metal structures are spaced apart from each other in a first direction from the first device region toward the second device region; forming an insulating layer surrounding the semiconductor components and the metal structures on the semiconductor substrate; forming an interconnection layer electrically connected to the semiconductor components on the insulating layer; and separating the first semiconductor component from the second semiconductor component by cutting the semiconductor substrate and the insulating layer of the scribe lane, wherein the metal structures are not cut when the first semiconductor component is separated from the second semiconductor component.

In accordance with an aspect of the disclosure, a semiconductor device includes a semiconductor substrate including a device region and an edge region; a semiconductor component on the device region; a test structure on the edge region, wherein the test structure is electrically insulated from the semiconductor component; and an insulating layer on the semiconductor substrate, the semiconductor component, and the test structure; and wherein the test structure is between the semiconductor component and a side surface of the insulating layer, and wherein the test structure is not exposed at the side surface of the insulating layer.

### BRIEF DESCRIPTION OF DRAWINGS

FIG. 1 is a plan view of a semiconductor device according to some embodiments.

FIGS. 2 and 3 are cross-sectional views of semiconductor devices according to some embodiments.

FIG. 4 is a plan view of a semiconductor device according to some embodiments.

FIG. 5 is a plan view of a wafer according to some embodiments.

FIGS. 6A, 7A, 8A, 9A and 10A are plan views of a method of manufacturing a semiconductor device according to some embodiments.

FIGS. 6B, 7B, 8B, 9B and 10B are cross-sectional views of a method of manufacturing a semiconductor device according to some embodiments.

FIG. 7C is a plan view of a method of manufacturing a semiconductor device according to some embodiments.

FIGS. 11A and 12A are plan views of a method of manufacturing a semiconductor device according to some embodiments.

FIGS. 11B and 12B are cross-sectional views of a method of manufacturing a semiconductor device according to some embodiments.

### DETAILED DESCRIPTION

Example embodiments will now be described more fully with reference to the accompanying drawings.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

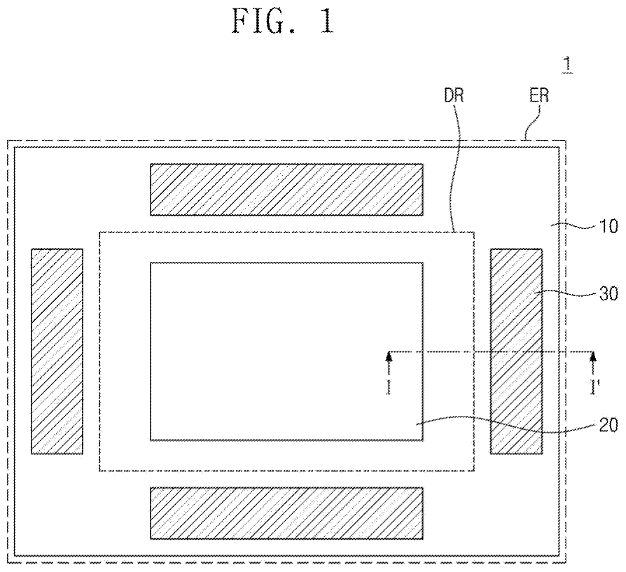

FIG. 1 is a plan view of a semiconductor device according to some embodiments. In embodiments, components of the semiconductor device shown in FIG. 1 may also include an interconnection layer and a protective layer, however for convenience in explanation and illustration, such elements are not illustrated in FIG. 1. FIG. 2 is a cross-sectional view taken along a line I-I′ of FIG. 1 to illustrate a semiconductor device according to some embodiments.

Referring to FIGS. 1 and 2, a semiconductor device 1 may include a semiconductor substrate 10 and a circuit structure CS disposed on the semiconductor substrate 10.

The semiconductor substrate 10 may include a semiconductor material. For example, the semiconductor substrate 10 may be a single-crystalline silicon (Si) substrate.

The semiconductor substrate 10 may have a device region DR and an edge region ER. When viewed in a plan view, the device region DR may be located in a central portion of the semiconductor substrate 10, and the edge region ER may surround the device region DR. The semiconductor substrate 10 may have a first surface 10a and a second surface 10b, which are opposite to each other. The first surface 10a of the semiconductor substrate 10 may be a front surface of the semiconductor substrate 10, and the second surface may be a back surface of the semiconductor substrate 10. Here, the first surface 10a of the semiconductor substrate 10 may be referred to as a surface of the semiconductor substrate on which a semiconductor component is mounted and/or interconnection lines and pads are formed, and the second surface 10b of the semiconductor substrate 10 may be referred to as a surface opposite to the front surface.

The circuit structure CS may be disposed on the semiconductor substrate 10. The circuit structure CS may include a device layer DL, an interconnection layer IL and a protective layer PL, which may be sequentially stacked on the first surface 10a of the semiconductor substrate 10.

The device layer DL may include a semiconductor component 20 and a metal structure 30.

The semiconductor component 20 may include transistors TR provided on the first surface 10a in the device region DR of the semiconductor substrate 10. For example, each of the transistors TR may include a source electrode and a drain electrode which are formed in an upper portion of the semiconductor substrate 10, a gate electrode disposed on the first surface 10a of the semiconductor substrate 10, and a gate insulating layer disposed between the semiconductor substrate 10 and the gate electrode. A single transistor TR is illustrated in FIG. 2, but embodiments are not limited thereto. The semiconductor component 20 may include a plurality of the transistors TR. In some embodiments, the semiconductor component 20 may include a shallow device isolation pattern, a logic cell and/or a plurality of memory cells on the first surface 10a of the device region DR. In certain embodiments, the semiconductor component 20 may include a passive component such as a capacitor. The semiconductor component 20 may be not disposed on the edge region ER of the semiconductor substrate 10.

The metal structure 30 may be provided on the first surface 10a of the edge region ER of the semiconductor substrate 10. The metal structure 30 may be in contact with the first surface 10a of the semiconductor substrate 10. The metal structure 30 may be a test pattern for testing the semiconductor device 1 in a manufacturing process of the semiconductor device 1. For example, the metal structure 30 may include a capacitor for testing. In embodiments, the metal structure 30 is referred to as the metal structure for convenience in description, but embodiments are not limited thereto. The metal structure 30 may not include only a metal and may include at least one of various components or structures for testing the semiconductor device 1.

The metal structure 30 may be disposed at a side of the semiconductor component 20. The semiconductor device 1 may include any number of the metal structure 30, and each of the metal structures 30 may be located at each side of the semiconductor component 20. Hereinafter, one metal structure 30 is described as an example.

The metal structure 30 may be located on the edge region ER between the semiconductor component 20 and a side surface 10c of the semiconductor substrate 10. The metal structure 30 may be shifted from the side surface 10c of the semiconductor substrate 10 in a direction toward the inside of the semiconductor substrate 10. In other words, the metal structure 30 may be spaced apart from the side surface 10c of the semiconductor substrate 10. For example, a distance gap1 between the metal structure 30 and the side surface 10c of the semiconductor substrate 10 may range from 2.5 μm to 20 μm. The metal structure 30 may be spaced apart from the semiconductor component 20, or may be spaced apart from the device region DR.

The metal structure 30 may be electrically insulated from the semiconductor component 20. In addition, the metal structure 30 may be electrically insulated from other components and interconnection lines in the semiconductor device 1. In other words, the metal structure 30 may be floated in the semiconductor device 1. However, embodiments are not limited thereto. The metal structure 30 may be not disposed on the device region DR of the semiconductor substrate 10.

The first surface 10a of the semiconductor substrate 10 may be covered with or by a device interlayer insulating layer 40. The device interlayer insulating layer 40 may cover, or surround, the semiconductor component 20 on the device region DR. The device interlayer insulating layer 40 may cover, or surround, the metal structure 30 on the edge region ER. Here, the device interlayer insulating layer 40 may cover, or surround, the semiconductor component 20 and the metal structure 30 from above. In other words, the semiconductor component 20 and the metal structure 30 may be covered by, or surrounded by, the device interlayer insulating layer 40 and thus may not be exposed to the outside. A side surface 40a of the device interlayer insulating layer 40 may be aligned with the side surface 10c of the semiconductor substrate 10. For example, the side surface 40a of the device interlayer insulating layer 40 may be coplanar with the side surface 10c of the semiconductor substrate 10. Because the metal structure 30 may be spaced apart from the side surface 10c of the semiconductor substrate 10, the metal structure 30 may also be spaced apart from the side surface 40a of the device interlayer insulating layer 40. For example, the distance gap1 between the metal structure 30 and the side surface 40a of the device interlayer insulating layer 40 may range from 2.5 μm to 20 μm. For example, the device interlayer insulating layer 40 may include at least one of silicon oxide (e,g, SiO), silicon nitride (e,g, SiN), or silicon oxynitride (e,g, SiON). The device interlayer insulating layer 40 may have a mono-layered or multi-layered structure.

According to embodiments, the metal structure 30 may be provided on the edge region ER of the semiconductor substrate 10. When an impact or stress is applied from a side of the semiconductor device 1 toward the semiconductor component 20, the metal structure 30 may function as a partition wall of relieving the impact or stress and may protect the semiconductor component 20 from the impact or stress. In addition, the metal structure 30 may be a component provided for testing in a manufacturing process of the semiconductor device 1, and may be not used in driving of the completed semiconductor device 1. In other words, the metal structure 30 may absorb a large amount of the impact or stress regardless of damage to the metal structure 30. Thus, the semiconductor component 20 may be sufficiently or reliably protected from the impact or stress, and the semiconductor device 1 with improved structural stability may be provided.

On the device region DR, contact plugs 22 connected to the transistors TR may be disposed in the device interlayer insulating layer 40. Each of the contact plugs 22 may vertically penetrate the device interlayer insulating layer 40 in order to be connected to the source electrode, the drain electrode or the gate electrode of a corresponding one of the transistors TR. In embodiments, the contact plugs 22 may be connected to various components of the semiconductor component 20. The contact plugs 22 may vertically penetrate the device interlayer insulating layer 40 and thus may be exposed at a top surface of the device interlayer insulating layer 40. For example, the contact plugs 22 may include tungsten (W).

In embodiments, a side surface and a bottom surface of each of the contact plugs 22 may be covered with or by a seed layer or a barrier layer. The seed layer or the barrier layer may be disposed between the contact plug 22 and the device interlayer insulating layer 40. For example, the seed layer may include gold (Au). For example, the barrier layer may include at least one of titanium (Ti), titanium nitride (e,g, TiN), tantalum (Ta), tantalum nitride (e,g, TaN), or tungsten nitride (e,g, WN).

The semiconductor component 20, the transistors TR of the semiconductor component 20, the device interlayer insulating layer 40 and the contact plugs 22 may be included in the device layer DL.

The interconnection layer IL may be disposed on the device interlayer insulating layer 40. The interconnection layer IL may cover the device region DR and the edge region ER of the semiconductor substrate 10. In other words, the metal structure 30 may be covered with or by the interconnection layer IL when viewed in a plan view.

The interconnection layer IL may include an insulating stack 51. The insulating stack 51 may include a plurality of stacked lower inter-metallic dielectric layers 52. The lower inter-metallic dielectric layers 52 may include a low-k dielectric material. In particular, a dielectric constant of the lower inter-metallic dielectric layers 52 may be less than a dielectric constant of the material of the device interlayer insulating layer 40, which may be for example silicon oxide (e,g, SiO). For example, the lower inter-metallic dielectric layers 52 may be porous insulating layers. A mechanical strength of each of the lower inter-metallic dielectric layers 52 may be less than a mechanical strength of the device interlayer insulating layer 40.

In embodiments, an etch stop layer may be disposed between the lower inter-metallic dielectric layers 52. For example, the etch stop layer may be provided on a bottom surface of the lower inter-metallic dielectric layer 52. For example, the etch stop layer may include silicon nitride (e,g, SiN), silicon oxynitride (e,g, SiON), or silicon carbonitride (e,g, SiCN).

The interconnection layer IL may include a plurality of lower interconnection patterns 53 disposed in the insulating stack 51, and lower via patterns 54 connecting them 51. The lower interconnection patterns 53 and the lower via patterns 54 may be located on the device region DR of the semiconductor substrate 10. However, embodiments are not limited thereto, and in certain embodiments, the lower interconnection patterns 53 may extend from the device region DR onto the edge region ER of the semiconductor substrate 10, and some of the lower via patterns 54 may be located on the edge region ER.

The lower interconnection patterns 53 may correspond to horizontal interconnection lines for providing redistribution of electrical connection in the interconnection layer IL. Each of the lower interconnection patterns 53 may horizontally extend in a corresponding one of the lower inter-metallic dielectric layers 52. Lowermost ones of the lower interconnection patterns 53 may be connected to the contact plugs 22 on the device region DR, respectively. The lower interconnection patterns 53 may be electrically connected to the semiconductor component 20 through the contact plugs 22.

The lower via patterns 54 may correspond to vertical interconnection lines vertically connecting the lower interconnection patterns 53. Each of the lower via patterns 54 may vertically penetrate a corresponding one of the lower inter-metallic dielectric layers 52 to connect the lower interconnection patterns 53 vertically adjacent to each other.

The lower interconnection patterns 53 and the lower via patterns 54 may be provided as individual components as illustrated in FIG. 2. In embodiments, unlike FIG. 2, the lower interconnection pattern 53 and the lower via pattern 54 which are connected to each other may include the same material and may be provided in one body. The lower interconnection patterns 53 and the lower via patterns 54 may include a conductive material. For example, the lower interconnection patterns 53 and the lower via patterns 54 may include copper (Cu).

In embodiments, side surfaces and bottom surfaces of the lower interconnection pattern 53 and the lower via pattern 54 may be covered with or by a seed layer or a barrier layer. The seed layer or the barrier layer may be disposed between the lower interconnection pattern 53 and the lower inter-metallic dielectric layer 52 and between the lower via pattern 54 and the lower inter-metallic dielectric layer 52. For example, the seed layer may include gold (Au). For example, the barrier layer may include at least one of titanium (Ti), titanium nitride (e,g, TiN), tantalum (Ta), tantalum nitride (e,g, TaN), or tungsten nitride (e,g, WN).

The lower inter-metallic dielectric layers 52, the lower interconnection patterns 53 and the lower via patterns 54 may be included in the interconnection layer IL. A side surface of the interconnection layer IL (e.g, side surfaces of the lower inter-metallic dielectric layers 52) may be aligned with the side surface 10c of the semiconductor substrate and the side surface 40a of the device interlayer insulating layer 40. For example, the side surface of the interconnection layer IL may be coplanar with the side surface 10c of the semiconductor substrate 10 and the side surface 40a of the device interlayer insulating layer 40.

An upper inter-metallic dielectric layer 55 may be disposed on the interconnection layer IL. The upper inter-metallic dielectric layer 55 may include an insulating material. Here, a dielectric constant of the upper inter-metallic dielectric layer 55 may be greater than that of the lower inter-metallic dielectric layers 52. A mechanical strength of the upper inter-metallic dielectric layer 55 may be greater than the mechanical strength of the lower inter-metallic dielectric layers 52. A single upper inter-metallic dielectric layer 55 is illustrated in FIG. 2, but embodiments are not limited thereto. In embodiments, a plurality of upper inter-metallic dielectric layers 55 may be provided. In this case, the upper inter-metallic dielectric layers 55 may be sequentially stacked on the interconnection layer IL. For example, the upper inter-metallic dielectric layer 55 may include silicon oxide (e,g, SiO), tetraethyl orthosilicate (e,g, TEOS), or a high-density plasma (HDP) oxide. In embodiments, the upper inter-metallic dielectric layer 55 may include silicon nitride (e,g, SiN), and in this case, the upper inter-metallic dielectric layer 55 may function as an etch stop layer. In embodiments, the upper inter-metallic dielectric layer 55 may include a material having a low hydrogen permeability, and in this case, the upper inter-metallic dielectric layer 55 may function as a hydrogen blocking layer. For example, the material having the low hydrogen permeability may include at least one of aluminum oxide (e,g, AlO), tungsten oxide (e,g, WO), or silicon nitride (e,g, SiN). The upper inter-metallic dielectric layer 55 may have a mono-layered or multi-layered structure.

Sub-pads 56 may be disposed on the upper inter-metallic dielectric layer 55. The sub-pads 56 may be disposed on a top surface of the upper inter-metallic dielectric layer 55. The sub-pads 56 may be located on the device region DR of the semiconductor substrate 10.

Upper via patterns 57 may penetrate the upper inter-metallic dielectric layer 55. Each of the upper via patterns 57 may connect a corresponding one of the lower interconnection patterns 53 and a corresponding one of the sub-pads 56. The sub-pads 56 may be electrically connected to the semiconductor component 20 through the upper via patterns 57 and the interconnection layer IL. The upper via patterns 57 and the sub-pads 56 may include a conductive material. For example, the upper via patterns 57 and the sub-pads 56 may include copper (Cu).

In embodiments, upper interconnection lines may be additionally provided on the upper inter-metallic dielectric layer 55 of the device region DR. The upper interconnection lines may be spaced apart from the sub-pads 56 on the top surface of the upper inter-metallic dielectric layer 55. In embodiments, the upper interconnection lines may be provided in the upper inter-metallic dielectric layer 55. For example, when the upper inter-metallic dielectric layer 55 is provided as a multi-layer, for example when a plurality of the upper inter-metallic dielectric layer 55 are provided, the upper interconnection lines may be disposed in layers of the upper inter-metallic dielectric layer 55.

The protective layer PL may be disposed on the upper inter-metallic dielectric layer 55. The protective layer PL may cover the sub-pads 56 on the top surface of the upper inter-metallic dielectric layer 55. The protective layer PL may conformally cover the top surface of the upper inter-metallic dielectric layer 55 and the sub-pads 56. For example, the protective layer PL may have a thick first thickness TK1 on the device region DR on which the sub-pads 56 are provided on the top surface of the upper inter-metallic dielectric layer 55. The protective layer PL may have a thin second thickness TK2 on the edge region ER on which the sub-pads 56 are not provided on the top surface of the upper inter-metallic dielectric layer 55. The first thickness TK1 may be greater than the second thickness TK2. In other words, a distance from the first surface 10a of the semiconductor substrate 10 to a top surface of the protective layer PL on the device region DR may be greater than a distance from the first surface 10a of the semiconductor substrate 10 to the top surface of the protective layer PL on the edge region ER. The protective layer PL may include an HDP oxide, undoped silicate glass (USG), tetraethyl orthosilicate (e,g, TEOS), silicon nitride (e,g, SiN), silicon oxide (e,g, SiO), silicon oxycarbide (e,g, SiOC), silicon oxynitride (e,g, SiON), or silicon carbonitride (e,g, SiCN). The protective layer PL may have a mono-layered or multi-layered structure.

Bonding pads 65 may be disposed on the protective layer PL. The bonding pads 65 are located on a top surface of the protective layer PL in FIG. 2, but embodiments are not limited thereto. In certain embodiments, the protective layer PL may extend onto top surfaces of the bonding pads 65. The bonding pads 65 may be electrically connected to the sub-pads 56. The bonding pads 65 may include a conductive material. For example, the bonding pads 65 may include a metal such as copper (Cu).

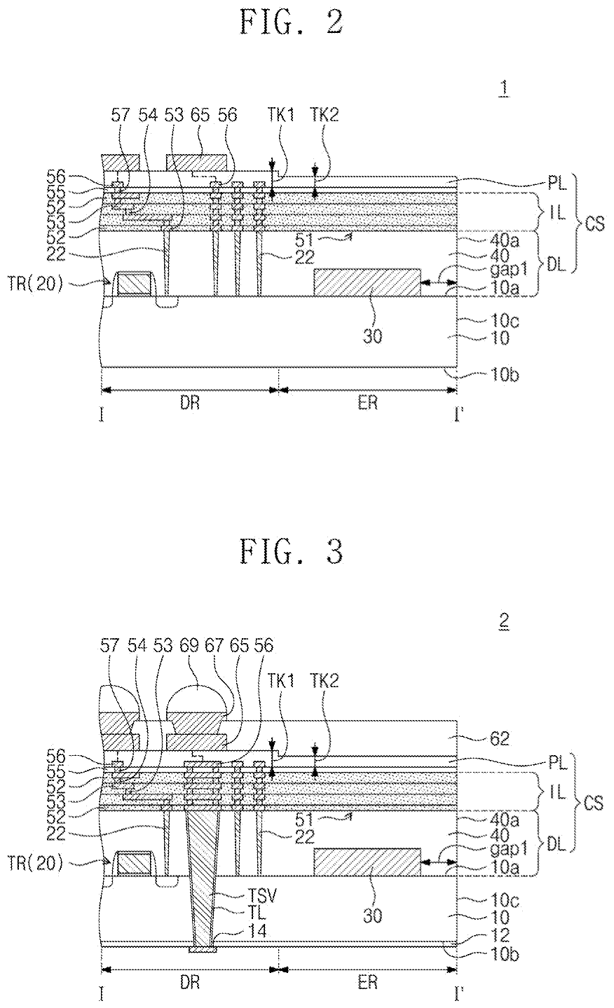

FIG. 3 is a cross-sectional view taken along the line I-I′ of FIG. 1 to illustrate a semiconductor device according to some embodiments. In the following embodiments, redundant descriptions of some elements mentioned above with reference to FIGS. 1 and 2 may be omitted, and differences between embodiments illustrated in FIG. 3 and embodiments illustrate in FIGS. 1 and 2 are mainly described below, for convenience in explanation. Hereinafter, the same or similar components as mentioned in the above embodiments are indicated by the same reference numerals or designators.

Referring to FIGS. 1 and 3, a semiconductor device 2 may be a die of a stack-type semiconductor package. For example, the semiconductor device 2 may include the semiconductor substrate 10, the circuit structure CS disposed on the front surface (e.g., the first surface 10a) of the semiconductor substrate 10, and a lower bonding pad 14 disposed on the back surface (e.g., the second surface 10b) of the semiconductor substrate 10.

The circuit structure CS may be disposed on the first surface 10a of the semiconductor substrate 10. The circuit structure CS may include the device layer DL, the interconnection layer IL and the protective layer PL, which may be sequentially stacked on the first surface 10a of the semiconductor substrate 10.

The device layer DL may include the semiconductor component 20, the metal structure 30, and the device interlayer insulating layer 40. The semiconductor component 20 may include the transistors TR provided on the first surface 10a of the device region DR of the semiconductor substrate 10. The metal structure 30 may be provided on the first surface 10a of the edge region ER of the semiconductor substrate 10. The device interlayer insulating layer 40 may cover the semiconductor component 20 on the device region DR. The device interlayer insulating layer 40 may cover the metal structure 30 on the edge region ER.

The interconnection layer IL may be disposed on the device interlayer insulating layer 40. The interconnection layer IL may include a plurality of the stacked lower inter-metallic dielectric layers 52, a plurality of the lower interconnection patterns 53 disposed in the lower inter-metallic dielectric layers 52, and the lower via patterns 54 connecting them 53.

The second surface 10b of the semiconductor substrate 10 may be covered with or by a lower protective layer 12. For example, the lower protective layer 12 may include silicon oxide (e,g, SiO), silicon nitride (e,g, SiN), or silicon carbonitride (e,g, SiCN). The lower protective layer 12 may have a mono-layered or multi-layered structure.

In the device region DR, a through-electrode TSV may penetrate the device interlayer insulating layer 40, the semiconductor substrate 10, and the lower protective layer 12. The through-electrode TSV may be in contact with a corresponding one of the lower interconnection patterns 53. For example, the through-electrode TSV may include a metal such as tungsten (W) or copper (Cu). A through-insulating layer TL may be disposed between the through-electrode TSV and the semiconductor substrate 10. For example, the through-insulating layer TL may include silicon oxide (e,g, SiO).

The lower bonding pad 14 may be disposed under the lower protective layer 12. The lower bonding pad 14 may be disposed on a bottom surface of the lower protective layer 12 and may be in contact with the through-electrode TSV. The lower bonding pad 14 may include a metal such as copper (Cu), gold (Au), nickel (Ni), or aluminum (Al).

The upper inter-metallic dielectric layer 55 may be disposed on the interconnection layer IL. The sub-pads 56 may be disposed on the upper inter-metallic dielectric layer 55. Each of the upper via patterns 57 may penetrate the upper inter-metallic dielectric layer 55 to connect a corresponding one of the lower interconnection patterns 53 and a corresponding one of the sub-pads 56.

The protective layer PL may be disposed on the upper inter-metallic dielectric layer 55. The bonding pads 65 may be disposed on the protective layer PL. The bonding pads 65 may be under bump pads.

A sub-protective layer 62 may be provided on the protective layer PL. The sub-protective layer 62 may have a flat top surface. In other words, the sub-protective layer 62 may function as a planarization layer. The sub-protective layer 62 may have a recess exposing at least a portion of a top surface of each of the bonding pads 65. A mechanical strength of the sub-protective layer 62 may be greater than the mechanical strength of the protective layer PL. The sub-protective layer 62 may include an HDP oxide, USG, tetraethyl orthosilicate (e,g, TEOS), silicon nitride (e,g, SiN), silicon oxide (e,g, SiO), silicon oxycarbide (e,g, SiOC), silicon oxynitride (e,g, SiON), or silicon carbonitride (e,g, SiCN). The sub-protective layer 62 may have a mono-layered or multi-layered structure.

Conductive bumps 67 may penetrate the sub-protective layer 62 in order to be in contact with the bonding pads 65. Each of the conductive bumps 67 may be disposed in a respective recess formed in the sub-protective layer 62. A portion of each of the conductive bumps 67 may protrude above the sub-protective layer 62. The conductive bumps 67 may include a metal. For example, the conductive bumps 67 may include copper (Cu). Solder layers 69 may be bonded onto the conductive bumps 67, respectively. For example, the solder layers 69 may include at least one of tin (Sn), lead (Pb), or silver (Ag).

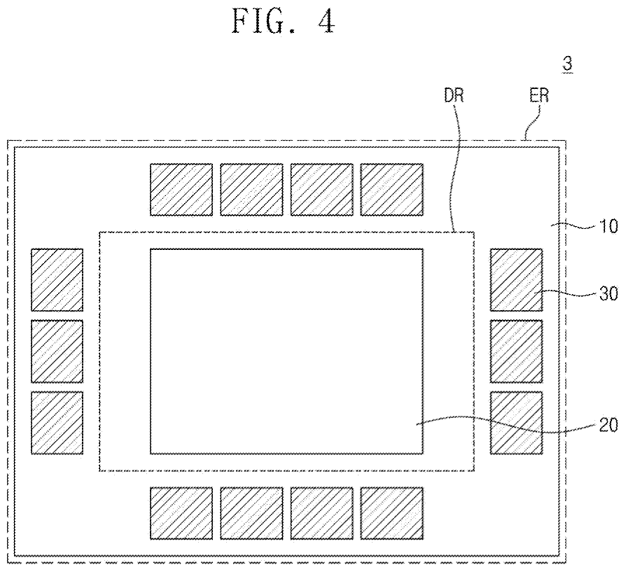

FIG. 4 is a plan view of a semiconductor device according to some embodiments.

As illustrated in FIGS. 1 to 3, single metal structure 30 may be provided at each of the sides of the semiconductor component 20, however embodiments are not limited thereto.

Referring to FIGS. 1 and 4, a plurality of metal structures 30 may be provided, and the metal structures 30 may be arranged in a line along an edge of the semiconductor component 20. For example, the plurality of the metal structures 30 may be located at one side of the semiconductor component 20, or a plurality of the metal structures 30 may be located at each side of the semiconductor component 20. For example, each of the metal structures 30 may be provided on the first surface 10a of the edge region ER of the semiconductor substrate 10. The metal structures 30 may be located on the edge region ER between the semiconductor component 20 and the side surface 10c of the semiconductor substrate 10. Each of the metal structures 30 may be shifted from the side surface 10c of the semiconductor substrate 10 in a direction toward the inside of the semiconductor substrate 10. The metal structures 30 may be spaced apart from the side surface 10c of the semiconductor substrate 10. For example, a distance by which each of the metal structures 30 is spaced apart from the side surface 10c of the semiconductor substrate 10 may range from 2.5 μm to 20 μm. The metal structures 30 at the one side of the semiconductor component 20 may be arranged in a direction parallel to the one side. The metal structures 30 may be provided as different components or structures as needed. Each of the metal structures 30 may be floated in a semiconductor device 3. In embodiments, the metal structures 30 may be electrically insulated from the semiconductor component 20, and some of the metal structures 30 may be electrically connected to each other.

According to some embodiments, components and interconnection lines for driving the semiconductor device 3 may be provided on the device region DR, and the edge region ER may be a residual region on which the components and the interconnection lines may be not provided. The plurality of metal structures 30 may be provided on the edge region ER, and thus may assist in performing a test process in a manufacturing process of the semiconductor device 3. In addition, because a plurality of the metal structures 30 may be provided between the semiconductor component 20 and the side surface 40a of the device interlayer insulating layer 40, the metal structures 30 may more easily absorb external stress and impact. Thus, the semiconductor component 20 may be sufficiently or reliably protected from the impact or stress, and the semiconductor device 3 with improved structural stability may be provided.

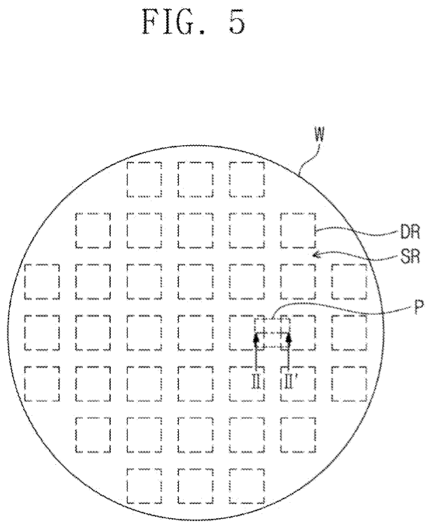

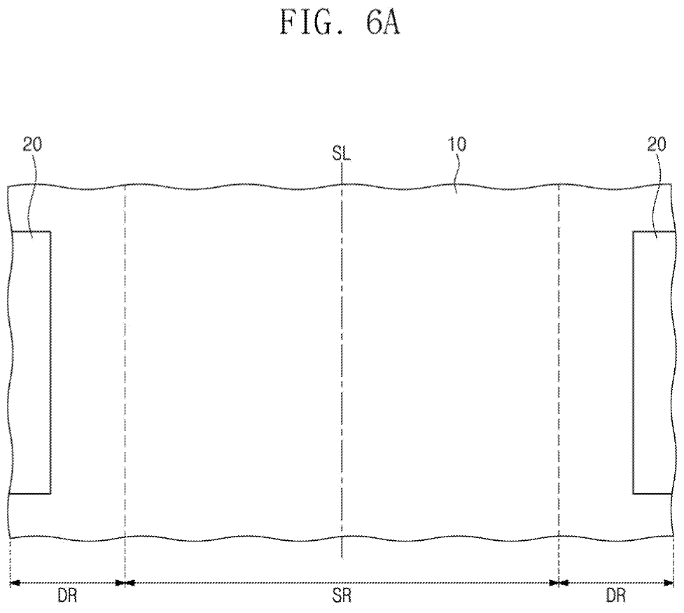

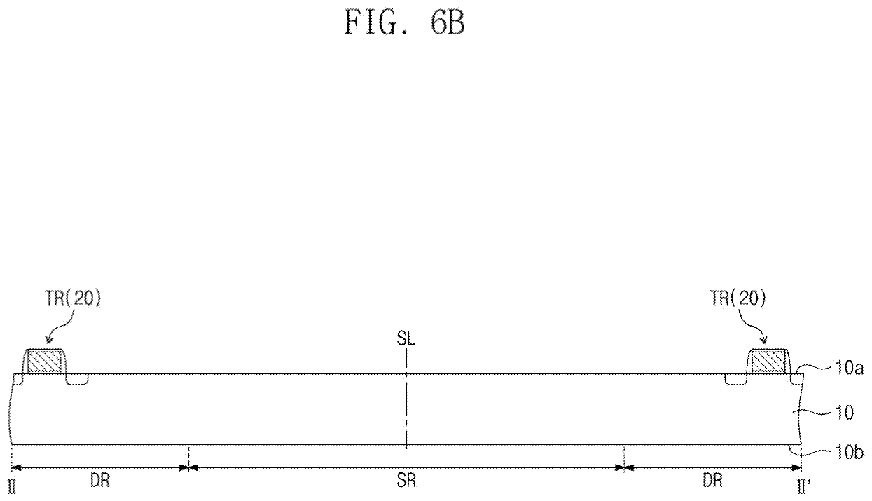

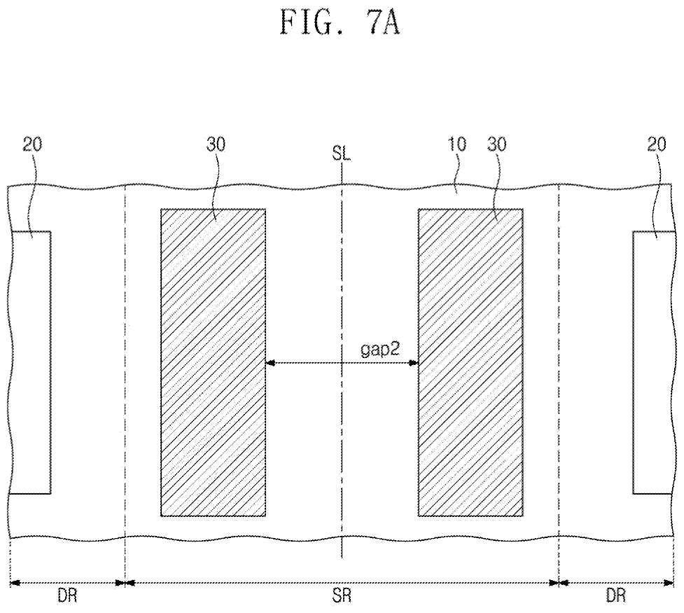

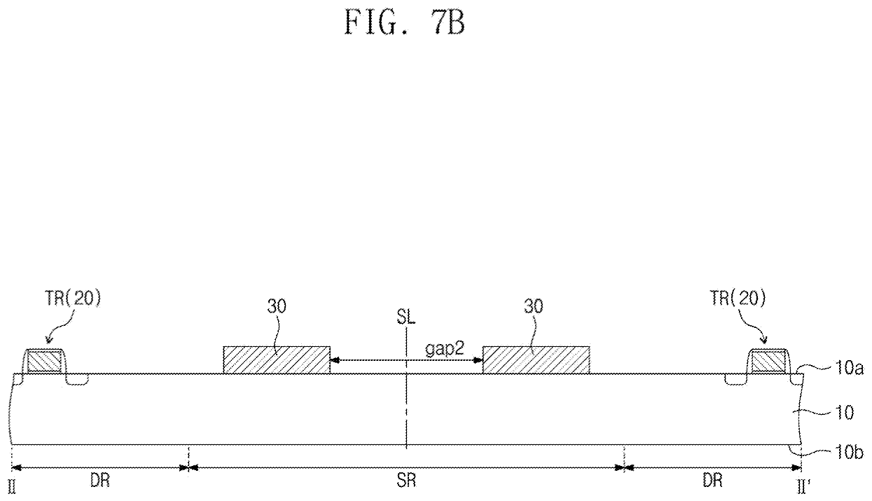

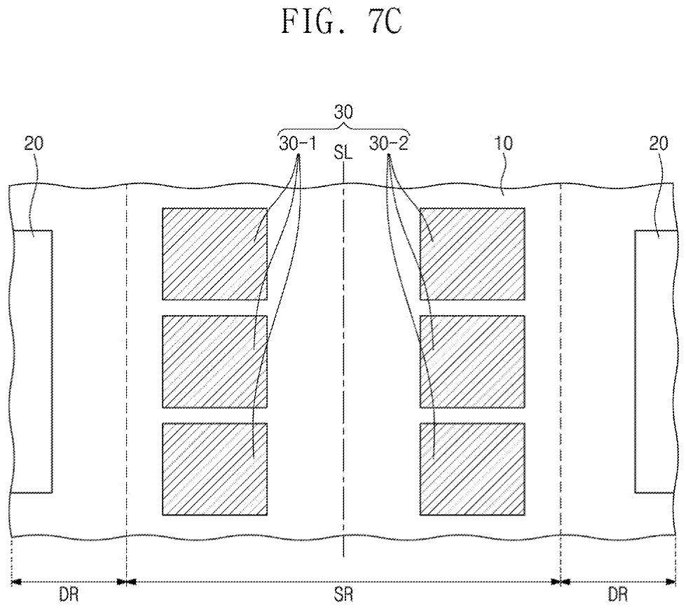

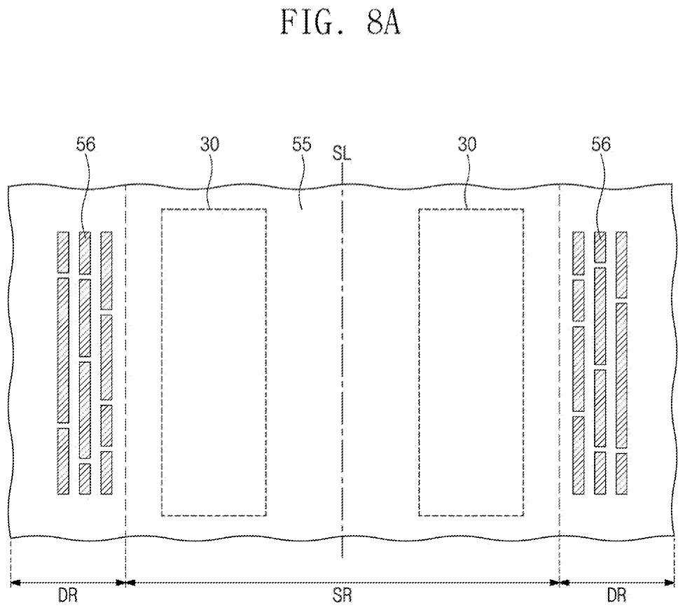

FIG. 5 is a plan view of a wafer. FIGS. 6A, 7A, 8A, 9A and 10A are plan views of a method of manufacturing a semiconductor device according to some embodiments. FIGS. 6B, 7B, 8B, 9B, and 10B are cross-sectional views of a method of manufacturing a semiconductor device according to some embodiments. FIG. 7C is a plan view of a method of manufacturing a semiconductor device according to some embodiments. FIGS. 6A to 10A and 7C correspond to enlarged views of a region ‘P’ of FIG. 5. FIGS. 6B to 10B correspond to cross-sectional views taken along a line II-IF of FIG. 5.

Referring to FIGS. 5, 6A and 6B, a wafer W may be provided. The wafer W may correspond to a semiconductor substrate 10 of FIG. 6B. A plurality of device regions DR may be arranged in the wafer W. Each of the device regions DR may also be referred to as a chip region. A scribe lane region SR may be disposed between the device regions DR. A cutting line SL may be set or defined on the scribe lane region SR. The cutting line SL may extend in a direction crossing between the device regions DR. The cutting line SL may be located at the middle of the scribe lane region SR. For example, distances from the device regions DR to the cutting line SL may be substantially equal or similar to each other.

Semiconductor components 20 may be formed on a first surface 10a of the semiconductor substrate 10 through general processes. For example, source electrodes and drain electrodes may be formed in an upper portion of the semiconductor substrate 10 of the device regions DR, and a gate insulating layer and a gate electrode may be formed on the semiconductor substrate 10 between the source electrode and the drain electrode, which may be adjacent to each other, thereby forming transistors TR.

Referring to FIGS. 5, 7A and 7B, metal structures 30 may be formed on the first surface 10a of the semiconductor substrate 10. For example, test capacitors may be formed on the scribe lane region SR. The metal structures 30 may be formed at the same time in the process of forming the semiconductor components 20, or may be formed by an additional process after the formation of the semiconductor components 20. The metal structures 30 may be spaced apart from each other on the scribe lane region SR. For example, the metal structures 30 may be spaced apart from each other with the cutting line SL interposed therebetween. Between the device regions DR adjacent to each other, each of the metal structures 30 may be formed between each of the adjacent device regions DR and the cutting line SL. In embodiments, the metal structures 30 may be spaced apart from the cutting line SL. A distance gap2 between the metal structures 30 may range from 5 μm to 100 μm.

As illustrated in FIG. 7A, single metal structure 30 may be formed adjacent to each of the adjacent device regions DR and between the adjacent device regions DR in FIG. 7A, however embodiments are not limited thereto. In certain embodiments, as illustrated for example in FIG. 7C, a plurality of metal structures 30 may be provided between the device regions DR adjacent to each other, and a plurality of the metal structures 30 may be formed between each of the adjacent device regions DR and the cutting line SL. For example, the metal structures 30 may include first metal structures 30-1 and second metal structures 30-2. The first metal structures 30-1 may be formed between one of the adjacent device regions DR and the cutting line SL, and the second metal structures 30-2 may be formed between the other of the adjacent device regions DR and the cutting line SL. The first metal structures 30-1 may be spaced apart from the second metal structures 30-2 with the cutting line SL interposed therebetween. The first metal structures 30-1 may be arranged in a direction parallel to a side of the semiconductor component 20 adjacent thereto or the cutting line SL. The second metal structures 30-2 may be arranged in the direction parallel to a side of the semiconductor component 20 adjacent thereto or the cutting line SL. In this case, the semiconductor device 3 described with reference to FIG. 4 may be manufactured. Hereinafter, embodiments illustrated in FIG. 7A are described as examples.

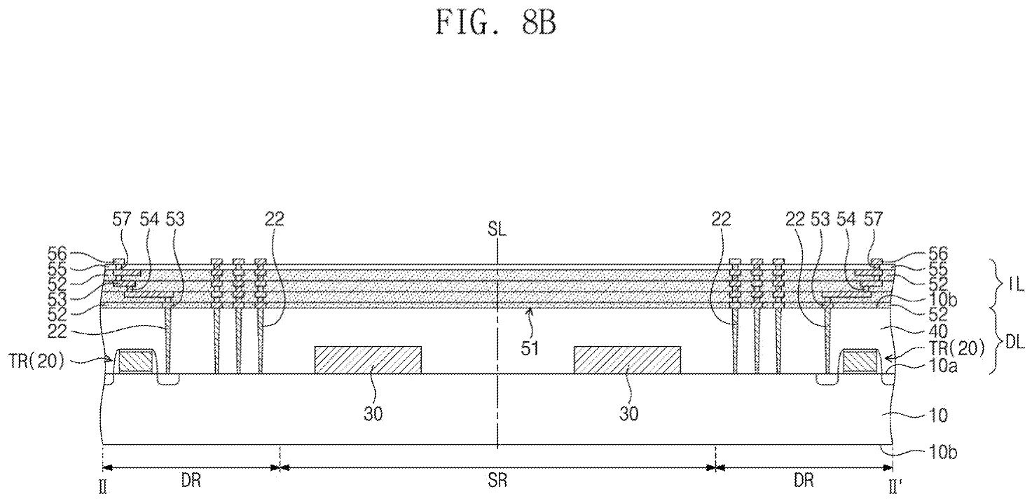

Referring to FIGS. 5, 8A and 8B, a device interlayer insulating layer 40 may be formed on the semiconductor substrate 10. For example, an insulating material may be deposited on the first surface 10a of the semiconductor substrate 10 to form the device interlayer insulating layer 40. The device interlayer insulating layer 40 may cover, or surround, the semiconductor components 20 on the device regions DR and may cover, or surround, the metal structures 30 on the scribe lane region SR.

Contact plugs 22 may be formed in the device interlayer insulating layer 40. For example, the device interlayer insulating layer 40 on the device regions DR may be etched to form holes exposing the semiconductor components 20, and then, the holes may be filled with a conductive material to form the contact plugs 22.

A device layer DL may be formed as described above.

In embodiments, the device layer DL and the semiconductor substrate 10 may be etched to form holes for through-electrodes, and through-electrodes TSV and through-insulating layers TL may be formed in the holes. In this case, the semiconductor device 2 described with reference to FIG. 3 may be manufactured. Hereinafter, embodiments illustrated in FIG. 8B are described as examples.

An interconnection layer IL may be formed on the device layer DL. The interconnection layer IL may include the insulating stack 51 including the plurality of stacked lower inter-metallic dielectric layers 52 of FIG. 2. Lower interconnection patterns 53 and lower via patterns 54 may be formed in the insulating stack 51. The lower interconnection patterns 53 and the lower via patterns 54 may be formed on the device regions DR.

An upper inter-metallic dielectric layer 55 may be formed on the interconnection layer IL. Upper via patterns 57 may be formed to penetrate the upper inter-metallic dielectric layer 55. Sub-pads 56 may be formed on the upper inter-metallic dielectric layer 55. The sub-pads 56 may be formed on the device regions DR.

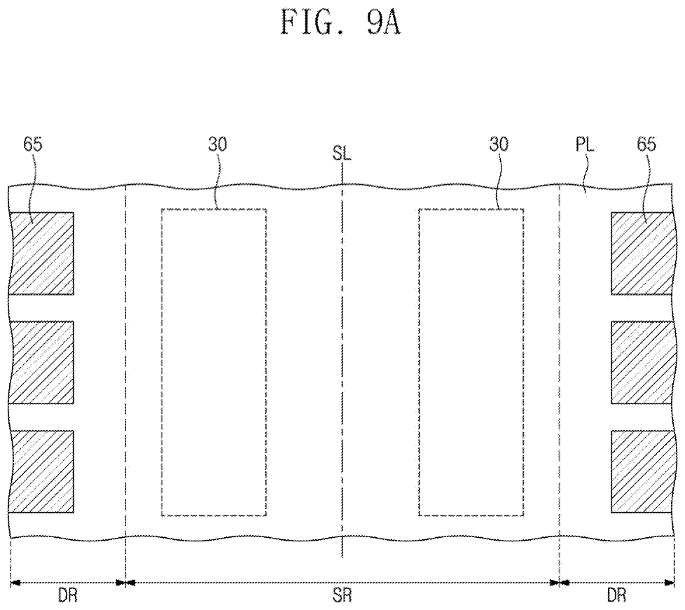

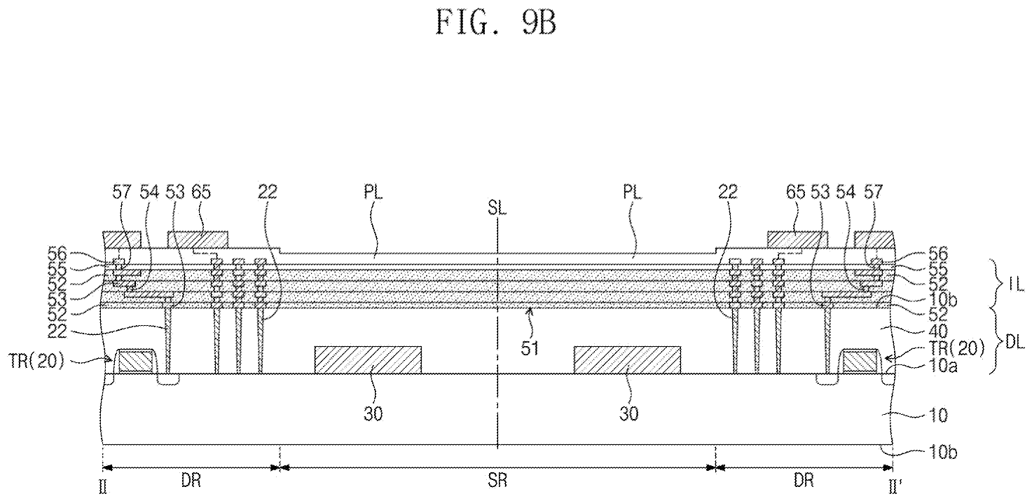

Referring to FIGS. 5, 9A and 9B, a protective layer PL may be formed on the upper inter-metallic dielectric layer 55. The protective layer PL may be conformally formed on the upper inter-metallic dielectric layer 55. At this time, the sub-pads 56 may be formed on the device regions DR, and the protective layer PL may cover the sub-pads 56. Thus, a top surface of the protective layer PL on the device regions DR may be located at a higher level than a top surface of the protective layer PL on the scribe lane region SR.

Even though not shown in the drawings, interconnection patterns connected to the sub-pads 56 may be provided in the protective layer PL.

Bonding pads 65 may be formed on the protective layer PL. For example, a metal-containing layer may be formed on the protective layer PL, and then, the metal-containing layer may be patterned to form the bonding pads 65. For example, the metal-containing layer may include aluminum (Al). In embodiments, a mask pattern may be formed on the protective layer PL, and then, pattern holes of the mask pattern may be filled with a conductive material to form the bonding pads 65. The bonding pads 65 may be formed on the device regions DR.

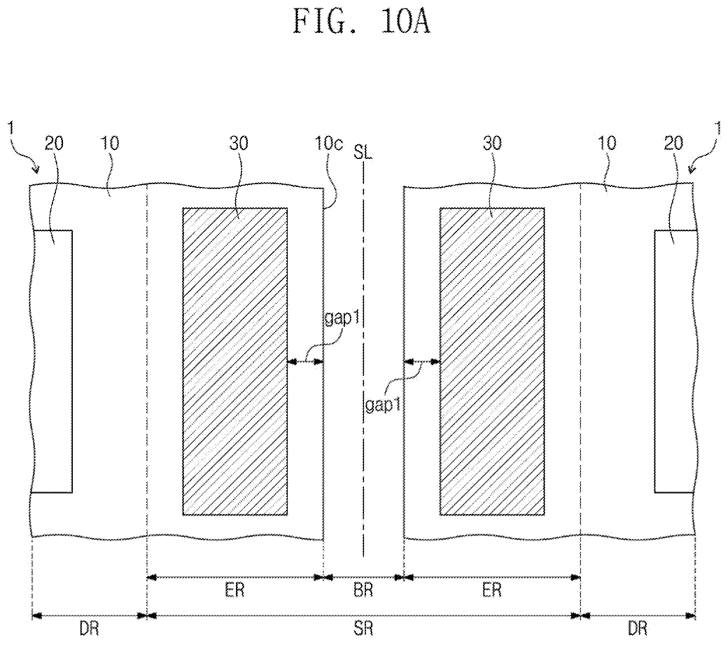

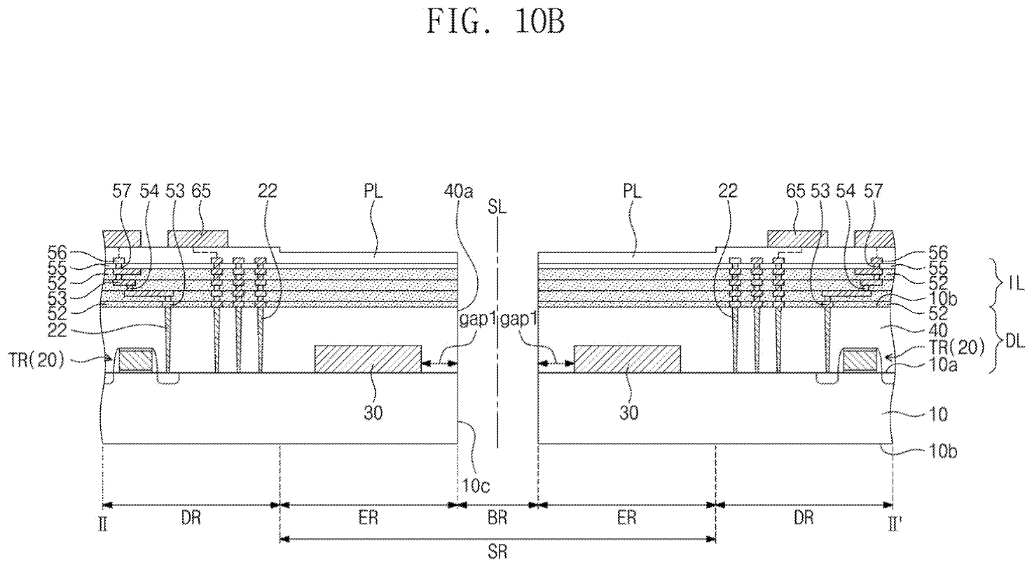

The protective layer PL and the interconnection layer IL are not illustrated in FIG. 10A for convenience in illustration. Referring to FIGS. 5, 10A and 10B, a sawing process may be performed using laser to remove a breaking region BR and to separate individual semiconductor devices 1 from each other. For example, the laser may be applied along or irradiate the cutting line SL, and the semiconductor substrate 10, the device interlayer insulating layer 40, the interconnection layer IL and the protective layer PL of the breaking region BR may be removed by the laser. After the sawing process, a remaining region of the scribe lane region SR except the breaking region BR may be referred to as an edge region ER of the semiconductor device 1.

Because the metal structures 30 may be spaced apart from the cutting line SL by a certain distance or more, the laser may sequentially pass through the semiconductor substrate 10, the device interlayer insulating layer 40, the interconnection layer IL and the protective layer PL but may not pass through the metal structures 30. Thus, after the sawing process, the metal structures 30 of the semiconductor devices 1 may not be exposed to the outside. For example, the metal structure 30 may be located on the first surface 10a of the semiconductor substrate 10 and may be covered with or by the device interlayer insulating layer 40. Here, the metal structure 30 may be spaced apart from a cut surface 40a of the device interlayer insulating layer 40 and a cut surface 10c of the semiconductor substrate 10. In other words, the metal structure 30 may be covered with or by the semiconductor substrate 10 and the device interlayer insulating layer 40 and thus may not be exposed to the outside. The cut surface 10c of the semiconductor substrate 10 may be coplanar with the cut surface of the device interlayer insulating layer 40.

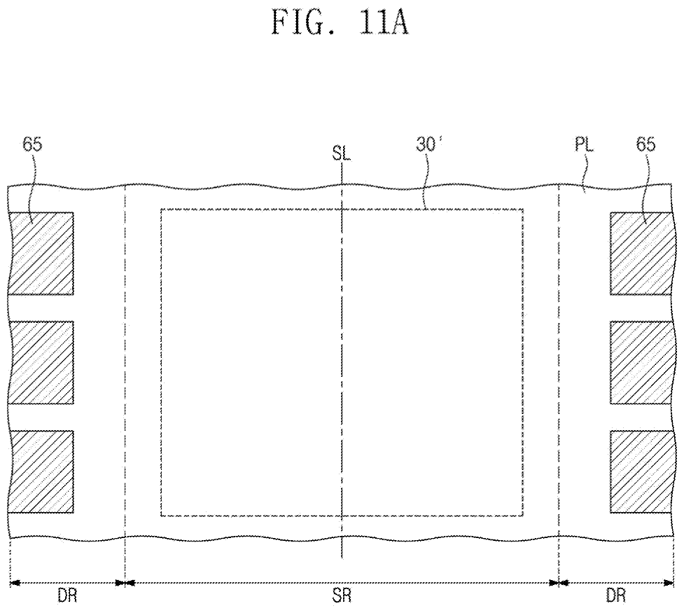

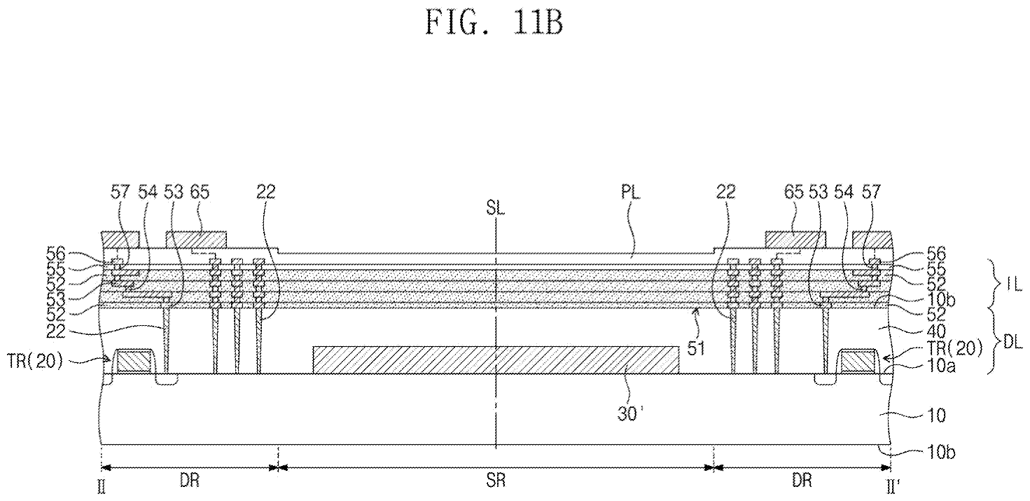

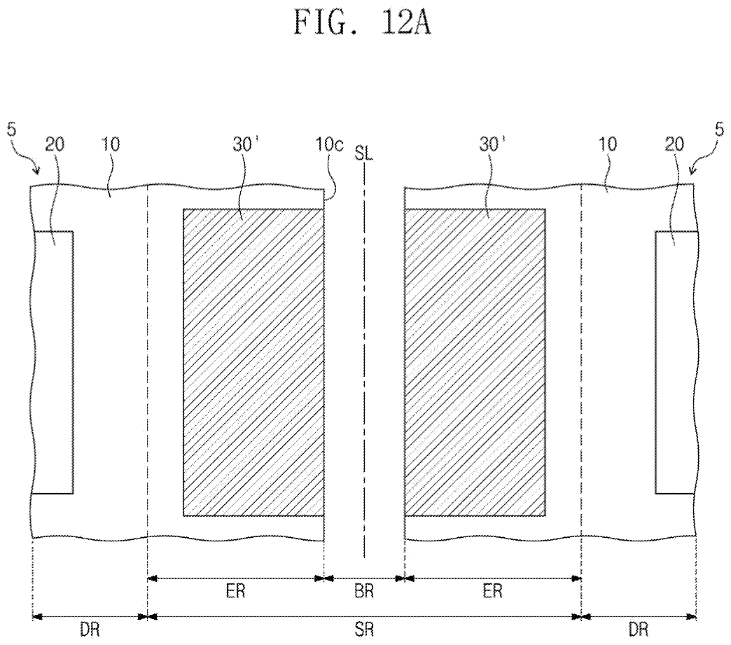

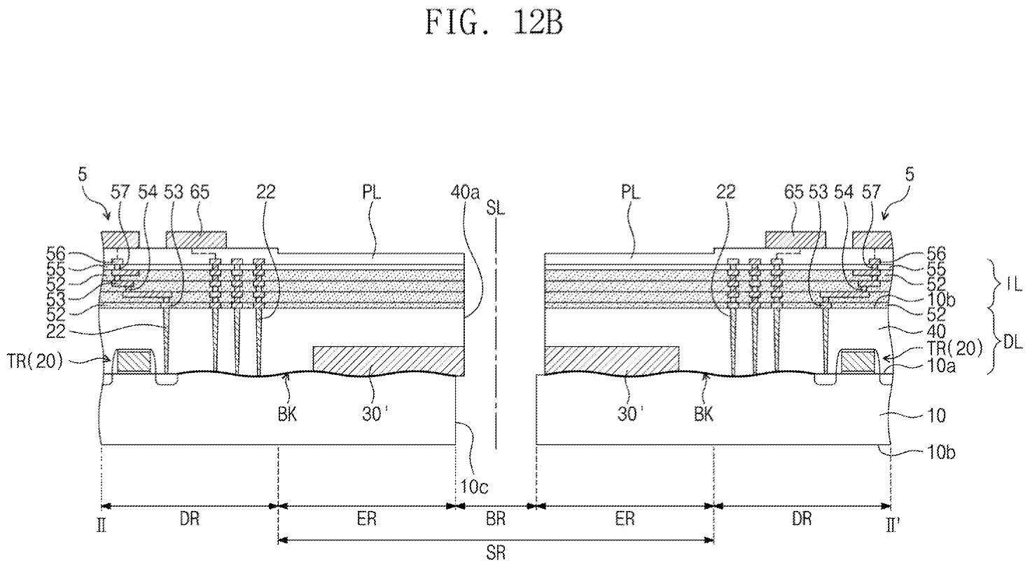

FIGS. 11A and 12A are plan views of a method of manufacturing a semiconductor device according to a comparative example. FIGS. 11B and 12B are cross-sectional views of a method of manufacturing a semiconductor device according to a comparative example.

Referring to FIGS. 11A and 11B, a metal structure 30′ may be formed on the first surface 10a of the semiconductor substrate 10 in the resultant structure of FIGS. 6A and 6B. A single metal structure 30′ may be formed between the device regions DR adjacent to each other. Here, the metal structure 30′ may be located on the cutting line SL between the device regions DR adjacent to each other.

Thereafter, the processes described with reference to FIGS. 7A to 9A and 7B to 9B may be performed. For example the device interlayer insulating layer 40, the interconnection layer IL and the protective layer PL may be formed on the semiconductor substrate 10.

Referring to FIGS. 12A and 12B, a sawing process may be performed using laser to remove a breaking region BR and to separate individual semiconductor devices 5 from each other. For example, the laser may be applied along or irradiate the cutting line SL, and the semiconductor substrate 10, the metal structure 30′, the device interlayer insulating layer 40, the interconnection layer IL and the protective layer PL of the breaking region BR may be removed by the laser. After the sawing process, a remaining region of the scribe lane region SR excluding the breaking region BR may be referred to as an edge region ER of the semiconductor device 5.

Because the metal structure 30′ may be located on the cutting line SL, the laser may sequentially cut the semiconductor substrate 10, the metal structure 30′ and the device interlayer insulating layer 40. Therefore, because a difference in hardness between the semiconductor substrate 10, the device interlayer insulating layer 40 and the metal structure 30′ may be large, a break phenomenon may occur at an interface between the semiconductor substrate 10 and the metal structure 30′ and an interface between the metal structure 30′ and the device interlayer insulating layer 40, or the metal structure 30′ may be delaminated from the semiconductor substrate 10. For example, when the laser cuts the semiconductor substrate 10 and then reaches a bottom surface of the metal structure 30′, the break phenomenon may occur at the interface between the semiconductor substrate 10 and the metal structure 30′, and a bonding defect BK may be generated along the interface between the semiconductor substrate 10 and the metal structure 30′. In embodiments, the bonding defect BK may refer to a failure in which two components bonded to each other are delaminated from each other or a gap or pore is formed between the two components. The bonding defect BK may be expanded along the interface between the semiconductor substrate and the metal structure 30′ or an interface between the semiconductor substrate 10 and the device interlayer insulating layer 40 and may damage the semiconductor component 20 on the device region DR. In embodiments, a cut surface 10c of the semiconductor substrate 10 may be horizontally shifted from a cut surface of the metal structure 30′ by the bonding defect BK, and thus a stepped shape may be formed at a side surface of the semiconductor device 5.

However, according to some embodiments, for example embodiments discussed above with respect to FIGS. 1 to 10B, because the metal structures 30 may be spaced apart from the cutting line SL by a certain distance or more, the metal structures 30 may be not cut by the laser. Thus, a break phenomenon may not occur at an interface between the semiconductor substrate 10 and the metal structure 30 and an interface between the metal structure 30 and the device interlayer insulating layer 40. In other words, the metal structures 30 may not receive an impact caused by the laser, and it may be possible to prevent the metal structures 30 from being delaminated from the semiconductor substrate 10 in the sawing process and/or to prevent a bonding defect from occurring at a bonding surface between the metal structures 30 (or the device interlayer insulating layer 40) and the semiconductor substrate 10. Thus, failure may not occur in a manufacturing process of the semiconductor device.

In the semiconductor device according to embodiments, when an impact or stress is applied from a side of the semiconductor device toward the semiconductor component, the metal structure may function as the partition wall for relieving the impact or stress and may protect the semiconductor component from the impact or stress. In addition, the metal structure may absorb a large amount of the impact or stress regardless of damage of the metal structure. Thus, the semiconductor component may be sufficiently or reliably protected from the impact or stress, and the semiconductor device with improved structural stability may be provided.

In the method of manufacturing a semiconductor device according to embodiments, because the metal structures may be spaced apart from the laser cutting line by a certain distance or more, the metal structures may not be cut by the laser. Thus, a break phenomenon may not occur at the interface between the semiconductor substrate and the metal structure and the interface between the metal structure and the device interlayer insulating layer. In other words, the metal structures may not receive an impact caused by the laser, and it is possible to prevent the metal structures from being delaminated from the semiconductor substrate in the sawing process and/or to prevent a bonding defect from occurring at the bonding surface between the metal structure (or the device interlayer insulating layer) and the semiconductor substrate in the sawing process. Thus, failure may not occur in a manufacturing process of the semiconductor device.

While some embodiments have been particularly shown and described, it will be understood by one of ordinary skill in the art that variations in form and detail may be made therein without departing from the spirit and scope of the attached claims.

1. A semiconductor device comprising:
a semiconductor substrate including a device region and an edge region;
a semiconductor component on the device region;
a metal structure on the edge region;
an insulating layer surrounding the semiconductor component and the metal structure; and
a pad on the semiconductor component,
wherein the metal structure is surrounded by the insulating layer and is not exposed at a side surface of the insulating layer, and
wherein the metal structure is electrically insulated from the semiconductor component.

2. The semiconductor device of claim 1, wherein the metal structure comprises a test pattern.

3. The semiconductor device of claim 2, wherein the test pattern comprises a capacitor.

4. The semiconductor device of claim 1, wherein a side surface of the semiconductor substrate is coplanar with the side surface of the insulating layer.

5. The semiconductor device of claim 1, further comprising an interconnection layer on the insulating layer,
wherein the pad is on the interconnection layer and is electrically connected to the interconnection layer.

6. The semiconductor device of claim 5, further comprising a protective layer on the interconnection layer,
wherein a distance between a top surface of the device region and a top surface of the protective layer is greater than a distance between a top surface of the edge region and the top surface of the protective layer.

7. The semiconductor device of claim 1, wherein the metal structure is on a top surface of the semiconductor substrate.

8. (canceled)

9. The semiconductor device of claim 1, further comprising a plurality of metal structures including the metal structure, and
wherein the plurality of metal structures are arranged on the edge region in a direction parallel to the side surface of the insulating layer.

10. A semiconductor device comprising:
a semiconductor substrate including a device region and an edge region which surrounds the device region;
a semiconductor component on a top surface of the device region;
a metal structure on a top surface of the edge region;
an interconnection layer on the semiconductor component and the metal structure; and
a pad on the interconnection layer on the device region,
wherein the pad is electrically connected to the interconnection layer, and
wherein the metal structure is spaced apart from a side surface of the semiconductor substrate in a direction toward an inside of the semiconductor substrate.

11. The semiconductor device of claim 10, further comprising an insulating layer surrounding the semiconductor component and the metal structure,
wherein the interconnection layer is on the insulating layer.

12. The semiconductor device of claim 11, wherein a side surface of the metal structure is spaced apart from a side surface of the insulating layer in the direction toward the inside of the semiconductor substrate.

13. The semiconductor device of claim 11, wherein the metal structure is surrounded by the insulating layer and is not exposed at a side surface of the insulating layer.

14. The semiconductor device of claim 11, wherein the side surface of the semiconductor substrate is coplanar with a side surface of the insulating layer.

15. The semiconductor device of claim 10, wherein the metal structure is electrically insulated from the semiconductor component.

16. The semiconductor device of claim 10, wherein the metal structure comprises a test pattern.

17. (canceled)

18. The semiconductor device of claim 10, further comprising a protective layer on the interconnection layer,
wherein a distance between the top surface of the device region and a top surface of the protective layer is greater than a distance between the top surface of the edge region and the top surface of the protective layer.

19. The semiconductor device of claim 10, wherein the metal structure is on the top surface of the semiconductor substrate.

20-30. (canceled)

31. A semiconductor device comprising:
a semiconductor substrate including a device region and an edge region;
a semiconductor component on the device region;
a test structure on the edge region, wherein the test structure is electrically insulated from the semiconductor component; and
an insulating layer on the semiconductor substrate, the semiconductor component, and the test structure; and
wherein the test structure is between the semiconductor component and a side surface of the insulating layer, and
wherein the test structure is not exposed at the side surface of the insulating layer.

32. The semiconductor device of claim 31, wherein the semiconductor component is included in a plurality of semiconductor components on the device region.

33. The semiconductor device of claim 31, wherein the test structure is included in a plurality of test structures on the device region,
wherein the plurality of test structures are between the semiconductor component and the side surface of the insulating layer, and
wherein the plurality of test structures are not exposed at the side surface of the insulating layer.
